(19) United States
(12) Patent Application Publication
(10) Pub. No.: US 2006/0256608 A1
(43) Pub. Date: Nov. 16, 2006

(54) Resistive memory device with improved data retention and reduced power

(75) Inventors: An Chen, Sunnyvale, CA (US); Sameer Haddad, San Jose, CA (US); Tzu-Ning Fang, Palo Alto, CA (US)

Correspondence Address: Paul J. Winters, 307 Cypress Point Drive, Mountain View, CA, 94043, US

(73) Assignee: Spansion LLC

(21) Appl. No.: 11/126,800

(22) Filed: May 11, 2005

(51) Int. Cl. G11C 11/00

(52) U.S. Cl. 365/148

(57) ABSTRACT

Provided herein is method of programming a resistive memory device, the resistive memory device including a first electrode, a second electrode, a passive layer between the first and second electrode, and an active layer between the first and second electrodes. In the programming method, an electrical potential is applied across the first and second electrodes from higher to lower potential in the direction from the active layer to the passive layer so that electronic charge carriers enter the active layer and are held by traps therein. In erasing the memory device, an electrical potential is applied across the first and second electrodes from higher to lower potential in the direction from the passive layer to the active layer so that electronic charge carriers are moved from the active layer.

### BACKGROUND OF THE INVENTION

1. Technical Field

This invention relates generally to memory devices, and more particularly, to resistive memory device operation and resistive memory structure.

2. Background Art

The volume, use and complexity of computers and electronic devices are continually increasing. Computers consistently become more powerful, new and improved electronic devices are continually developed (e.g., digital audio players, video players). Additionally, the growth and use of digital media (e.g., digital audio, video, images, and the like) have further pushed development of these devices. Such growth and development has vastly increased the amount of information desired/required to be stored and maintained for computer and electronic devices.

Generally, information is stored and maintained in one or more of a number of types of storage devices. Storage devices include long term storage mediums such as, for example, hard disk drives, compact disk drives and corresponding media, digital video disk (DVD) drives, and the like. The long term storage mediums typically store larger amounts of information at a lower cost, but are slower than other types of storage devices. Storage devices also include memory devices, which are often, but not always, short term storage mediums. Memory devices tend to be substantially faster than long term storage mediums. Such memory devices include, for example, dynamic random access memory (DRAM), static random access memory (SRAM), double data rate memory (DDR), flash memory, read only memory (ROM), and the like. Memory devices are subdivided into volatile and non-volatile types. Volatile memory devices generally lose their information if they lose power and typically require periodic refresh cycles to maintain their information. Volatile memory devices include, for example, random access memory (RAM), DRAM, SRAM and the like. Non-volatile memory devices maintain their information whether or not power is maintained to the devices. Non-volatile memory devices include, but are not limited to, ROM, programmable read only memory (PROM), erasable programmable read only memory (EPROM), flash memory and the like. Volatile memory devices generally provide faster operation at a lower cost as compared to non-volatile memory devices.

Memory devices generally include arrays of memory cells. Each memory cell can be accessed or “read”, “written”, and “erased” with information. The memory cells maintain information in an “off” or an “on” state, also referred to as “0” and “1”. Typically, a memory device is addressed to retrieve a specified number of byte(s) (e.g., 8 memory cells per byte). For volatile memory devices, the memory cells must be periodically “refreshed” in order to maintain their state. Such memory devices are usually fabricated from semiconductor devices that perform these various functions and are capable of switching and maintaining the two states. The devices are often fabricated with inorganic solid state technology, such as, crystalline silicon devices. A common semiconductor device employed in memory devices is the metal oxide semiconductor field effect transistor (MOSFET).

The use of portable computer and electronic devices has greatly increased demand for non-volatile memory devices. Digital cameras, digital audio players, personal digital assistants, and the like generally seek to employ large capacity non-volatile memory devices (e.g., flash memory, smart media, compact flash, and the like).

Because of the increasing demand for information storage, memory device developers and manufacturers are constantly attempting to increase storage capacity for memory devices (e.g., increase storage per die or chip). A postage-stamp-sized piece of silicon may contain tens of millions of transistors, each transistor as small as a few hundred nanometers. However, silicon-based devices are approaching their fundamental physical size limits. Inorganic solid state devices are generally encumbered with a complex architecture which leads to high cost and a loss of data storage density. The volatile semiconductor memories based on inorganic semiconductor material must constantly be supplied with electric current with a resulting heating and high electric power consumption in order to maintain stored information. Non-volatile semiconductor devices have a reduced data rate and relatively high power consumption and large degree of complexity. Typically, fabrication processes for such cells are also not reliable.

Therefore, there is a need to overcome the aforementioned deficiencies.

FIG. 1 illustrates a type of memory device 30, which includes advantageous characteristics for meeting these needs. The memory device 30 includes an electrode 32 (for example copper), a copper sulfide layer 34 on the electrode 32, an active layer 36, for example a copper oxide layer, on the layer 34, and an electrode 38 (for example titanium) on the active layer 36. Initially, assuming that the memory device 30 is unprogrammed, in order to program the memory device 30, ground is applied to the electrode 38, while a positive voltage is applied to electrode 32, so that an electrical potential V_{pg} (the “programming” electrical potential) is applied across the memory device 30 from a higher to a lower electrical potential in the forward direction of the memory device 30 (see FIG. 2, a plot of memory device current vs. electrical potential applied across the memory device 30). This potential is sufficient to cause copper ions to be attracted from the layer 34 toward the electrode 38 and into the active layer 36 (A) so that conductive filaments are formed, causing the active layer 36 (and the overall memory device 30) to be in a (forward) low-resistance or conductive state. Upon removal of such potential (B), the ions drawn into the active layer 36 during the programming step remain therein, so that the active layer 36 (and memory device 30) remain in a conductive or low-resistance state.

In the read step of the memory device 30 in its programmed (conductive) state, an electrical potential Vᵣ (the “read” electrical potential) is applied across the memory device 30 from a higher to a lower electrical potential in the forward direction of the memory device 30. This electrical potential is less than the electrical potential V_{pg} applied across the memory device 30 for programming (see above). In this situation, the memory device 30 will readily conduct current, which indicates that the memory device 30 is in its programmed state.

In order to erase the memory device, a positive voltage is applied to the electrode 38, while the electrode 32 is held at ground, so that an electrical potential Vₑᵣ (the “erase” electrical potential) is applied across the memory device 30 from a higher to a lower electrical potential in the reverse direction of the memory device 30. This potential is sufficient to cause copper ions to be repelled from the active layer 36 toward the electrode 32 and into the layer 34 (C), causing the active layer 36 (and the overall memory device 30) to be in a high-resistance or substantially non-conductive state. This state remains upon removal of such potential from the memory device 30.

In the read step of the memory device 30 in its erased (substantially non-conductive) state, the electrical potential Vᵣ is again applied across the memory device 30 from a higher to a lower electrical potential in the forward direction of the memory device 30, as described above. With the active layer 34 (and memory device 30) in a high-resistance or substantially non-conductive state, the memory device 30 will not conduct significant current, which indicates that the memory device 30 is in its erased state.

It will be understood that it is highly desirable that the memory device, when programmed, be capable of retaining its programmed state for a long period of time, i.e., until it is desired that the state be changed to its erased state. Likewise, it is highly desirable that the memory device, when erased, be capable of retaining that state for a long period of time as chosen. While the above described device is effective in operation, it has been found that over a period of time, the conductive filaments formed in the programmed device can break down, causing the conductivity of the memory device to be significantly reduced, so that the memory device undesirably loses its programmed state. It will be understood that it is highly desirable for the device to be capable of stably retaining its programmed and erased states as desired. Additionally, the program and erase operations described above require a relatively high current, in turn resulting in relatively high energy consumption. It will also be understood that it is desirable to decrease program and erase currents, to in turn reduce power consumption. It will also be understood that it is desirable to improve switching speeds of the device.

### DISCLOSURE OF THE INVENTION

Broadly stated, the present method is for changing the state of a memory device, the memory device having a first electrode, a passive layer on and in contact with the first electrode, an active layer on and in contact with the passive layer, and a second electrode on and in contact with the active layer. Programming of the device into a low resistance state involves moving electronic charge carriers into the active layer to increase the conductivity thereof, and erasing of the device into a high resistance state involves moving electronic charge carriers from the active layer to decrease the conductivity thereof.

The present invention is better understood upon consideration of the detailed description below, in conjunction with the accompanying drawings. As will become readily apparent to those skilled in the art from the following description, there are shown and described embodiments of this invention simply by way of the illustration of the best mode to carry out the invention. As will be realized, the invention is capable of other embodiments and its several details are capable of modifications and various obvious aspects, all without departing from the scope of the invention. Accordingly, the drawings and detailed description will be regarded as illustrative in nature and not as restrictive.

### BRIEF DESCRIPTION OF THE DRAWINGS

The novel features believed characteristic of the invention are set forth in the appended claims. The invention itself, however, as well as said preferred mode of use, and further objects and advantages thereof, will best be understood by reference to the following detailed description of illustrative embodiment when read in conjunction with the accompanying drawings, wherein:

FIG. 1 is a cross-sectional view of an above-described memory device;

FIG. 2 is a plot of current vs. voltage illustrating operating characteristics of the memory device of FIG. 1;

FIG. 3 is a cross-sectional view of a first embodiment of the present memory device;

FIG. 4 is a cross-sectional view of the memory device of FIG. 3 as part of an integrated circuit;

FIGS. 5-8 illustrate programming and erasing of the memory device of FIG. 3 in accordance with the present method;

FIG. 9 is a plot of current vs. voltage illustrating operating characteristics of the memory device of FIG. 3, in accordance with the present method of FIGS. 5-8;

FIG. 10 is a graph illustrating current and voltage in programming and reading the state of the device of FIG. 3;

FIG. 11 is a graph illustrating data retention of the device of FIG. 3 when practicing the present method; and

FIGS. 12-15 illustrate programming and erasing of a second embodiment of memory device in accordance with the present method.

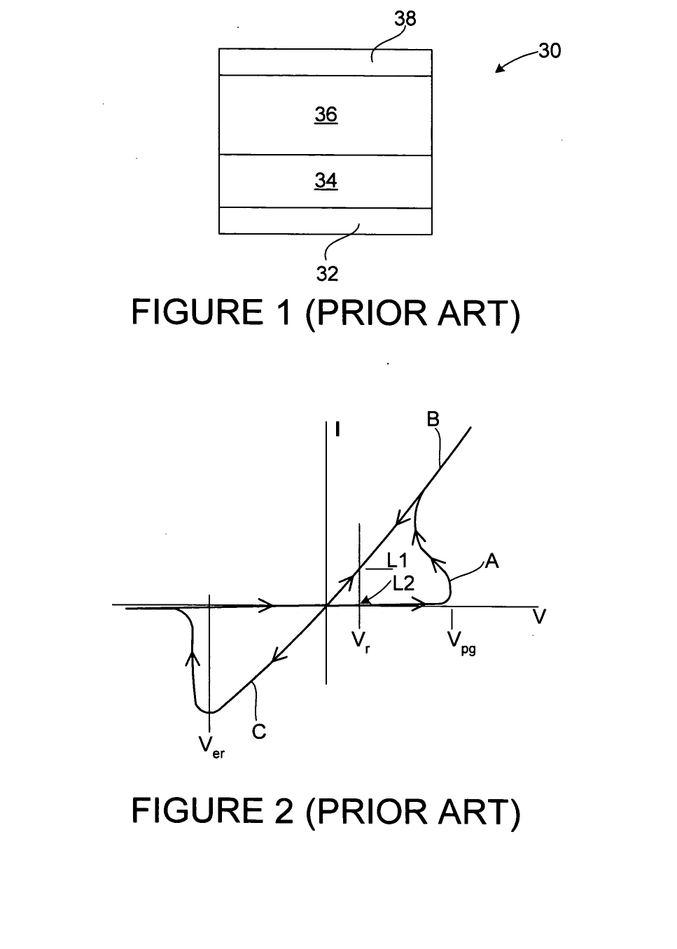

### BEST MODE(S) FOR CARRYING OUT THE INVENTION

Reference is now made in detail to specific embodiments of the present invention which illustrate the best mode presently contemplated by the inventors for practicing the invention.

Reference is made to the paper “The role of space-charge-limited-current conduction in evaluation of the electrical properties of thin Cu₂O films”, A. E. Rakhshani, J. Apl. Phys. 69(4), 15 Feb. 1991, pages 2365-2369, incorporated by reference herein.

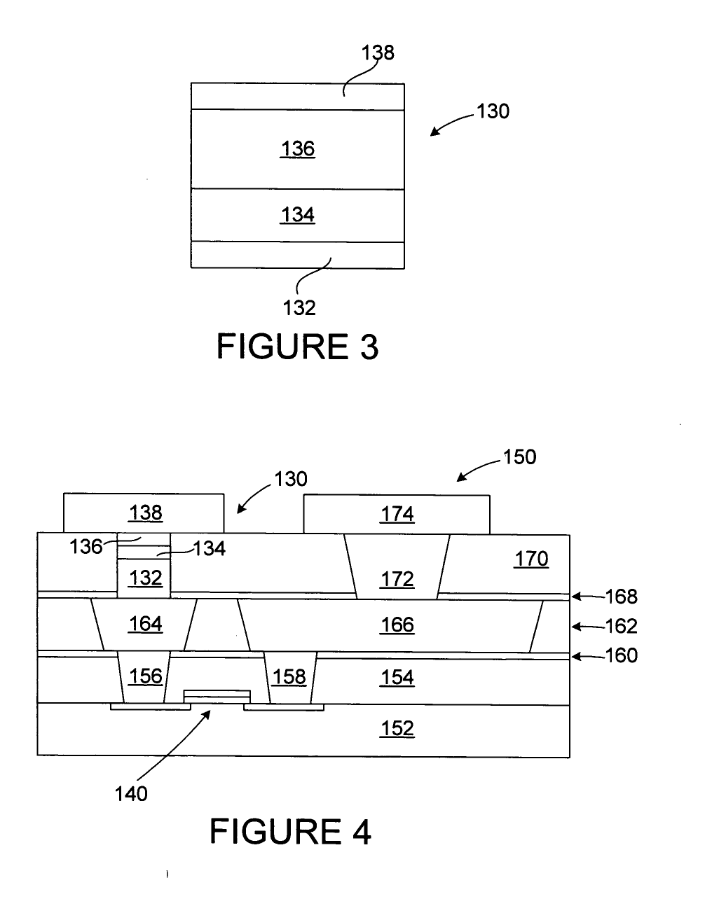

FIG. 3 illustrates a first embodiment of memory device 130 for use in the present invention. Initially, a copper electrode 132 is formed. The surface thereof is sulfidized using H₂S, elemental S or aqueous Ammonium Sulfate to form a 20-100 angstroms thick Cu₂S passive layer 134 on and in contact with the electrode 132. The surface of the layer 134 is oxidized to form a 30-200 angstroms thick copper oxide active layer 136 on and in contact with the passive layer 134. This manufacturing process forms deep charge carrier traps in the active layer 136. A titanium electrode 138 is formed on and in contact with the active layer 136 by for example DC or RF sputtering or by evaporation. FIG. 3 illustrates the fabricated memory device 130, wherein the layers 134, 136 are formed between the electrodes 132, 138.

FIG. 4 illustrates the memory device 130 as part of a larger electronic structure 150. The structure 150 includes a semiconductor substrate 152 having formed therein the source and drain of a transistor 140. Provided on the substrate 152 is a dielectric layer 154, which in turn has a nitride layer 160 thereon. Copper plugs 164, 166 extend through the dielectric and nitride layers 154, 160 and contact the source and drain of the transistor 140.

Overlying this structure is another dielectric layer 162. Copper plugs 164, 166 extend through the dielectric layer 162 and contact the copper plugs 156, 158 respectively. A nitride layer 168 is provided on the resulting structure, and a dielectric layer 170 is provided on the nitride layer 168. A copper plug 172 extends through the nitride and dielectric layers 168, 170 and contacts the copper plug 166. The electrode 132, passive layer 134, and active layer 136, in a stacked configuration, extend through the nitride and dielectric layers 168, 170, the electrode 132 contacting the copper plug 164. Electrode 138 is formed on the active layer 136, so that the overall memory device 130 is formed. An electrode 174 is formed in contact with the copper plug 172.

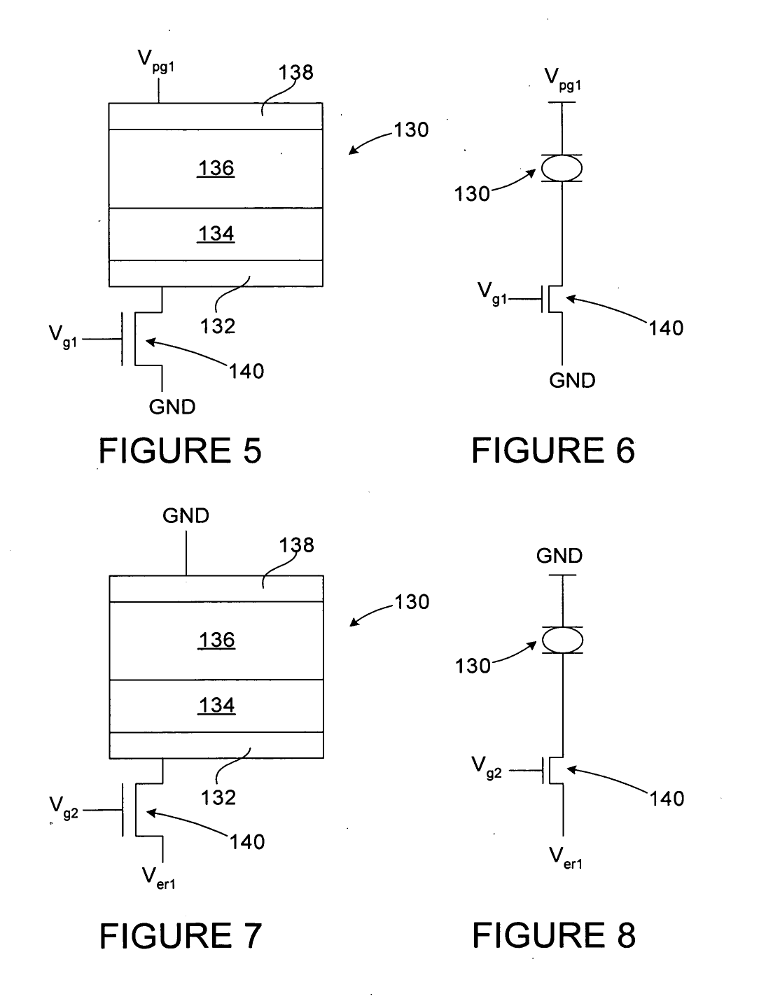

It will be seen that the memory device 130 is connected in series with the transistor 140. FIGS. 5-8 illustrate this configuration and also illustrate the present method.

In programming the memory device 130 (FIG. 5 and 6), a positive voltage V_{pg1} is applied to the electrode 138, while the source of the transistor 140 is connected to ground, so that an electrical potential is applied across the electrodes 138, 132 from a higher to a lower potential in the direction from the electrode 138 to the electrode 132 (and in the direction from active layer 136 to the passive layer 134). The voltage V_{g1} applied to the gate of the transistor 140 is set to a level so as to limit current through the device 130 during the programming operation. The programming operation causes electronic charge carriers, i.e., electrons and/or holes, to move into and be held by the preexisting traps in the active layer 136. The electronic charge carriers may be electrons, holes, or a combination of electrons and holes. The movement of these electronic charge carriers causes the active layer 136 (and the overall memory device 130) to adopt and be in a low-resistance or conductive state, i.e., a programmed state. Upon removal of such potential, the electronic charge carriers drawn into the active layer 136 during the programming step remain in and are held by the deep traps, so as to remain in the active layer 136, so that the active layer 136 (and memory device 130) remain in a conductive or low-resistance state.

In erasing the memory device 130 (FIGS. 7 and 8), ground is applied to the electrode 138, while a positive voltage Vₑᵣ₁ is applied to the source of the transistor 140, so that an electrical potential is applied across the electrodes 138, 132 from a higher to a lower potential in the direction from the electrode 132 to the electrode 138 (and in the direction from the passive layer 134 to the active layer 136). The voltage V_{g2} of the gate of the transistor 140 is set to a level so as to limit current through the device 130 during the erase operation. This operation causes the electronic charge carriers to move from the active layer 136. The movement of these electronic charge carriers causes the active layer 136 (and the overall memory device 130) to be in a high-resistance state or erased state. Upon removal of such potential, this erased state is maintained so that the active layer 136 (and memory device 130) remain in an erased or high-resistance state.

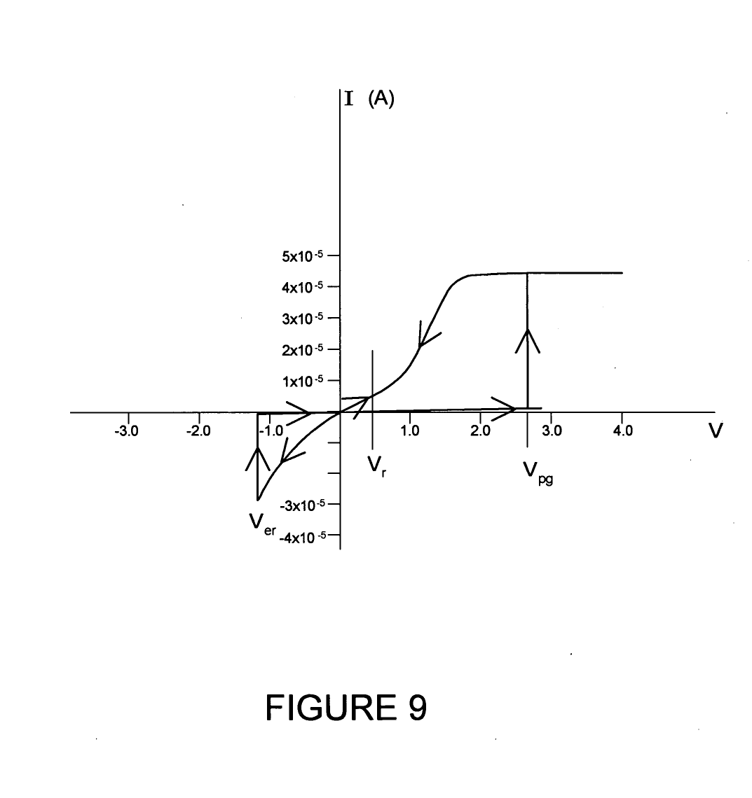

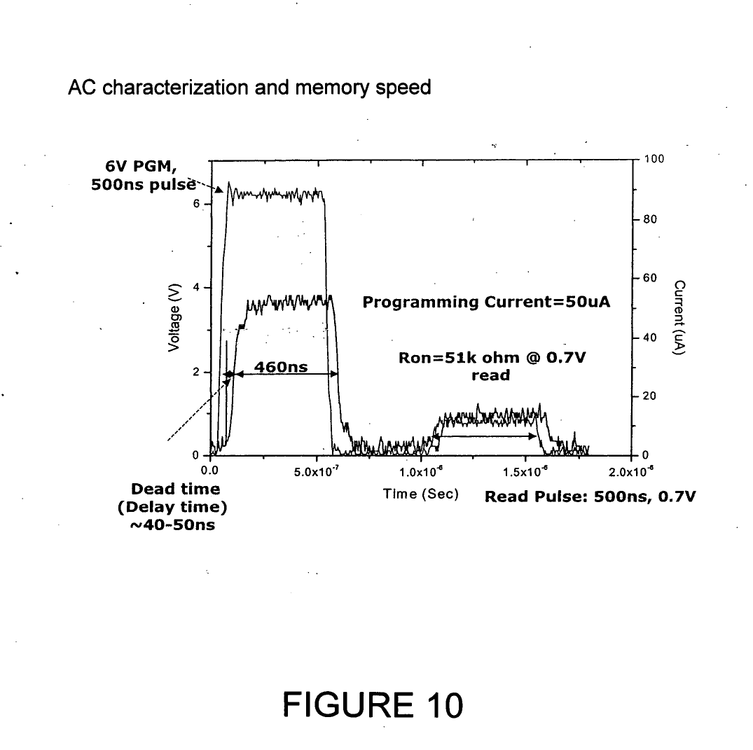

FIG. 9 illustrates the advantageous operating characteristics of the memory device 130 when practicing the present method, which takes the form of electronic switching (movement of electrons and/or holes) as compared to the prior art ionic switching. It has been found that the device 130 can effectively be programmed (changed from a high-resistance to a low-resistance state) by applying a V_{pg1} of less than 4 volts in accordance with the above description (FIG. 9 illustrates programming voltage V_{pg1}=2.7 volts, with ground applied as described above). The switching from erased to programmed state is very rapid (see FIG. 10), and the current limiting transistor 140, with gate set at for example 2.0 volts, limits the current in the programming operation to a very low level (illustrated as approximately 45 μa in FIG. 9). Likewise, it has been found that the device 130 can effectively be erased (changed from a low-resistance to a high-resistance state) by applying approximately Vₑᵣ=approximately 1.2 volts in accordance with the above description (FIG. 9 illustrates erase voltage Vₑᵣ=1.2 volts with ground applied as described above). Again, the switching from the programmed to the erased state is very rapid. With the current limiting transistor 140 gate voltage set at for example 4.0 volts, and because of the very low erase voltage, the current in the erase operation is very low. Thus, rapid switching and low power usage are achieved.

As illustrated in FIG. 9, the device (both programmed and erased) exhibits non-linear current characteristics (see curves A and B). This non-linear characteristic results from space-charge-limited-current conduction within the device 130.

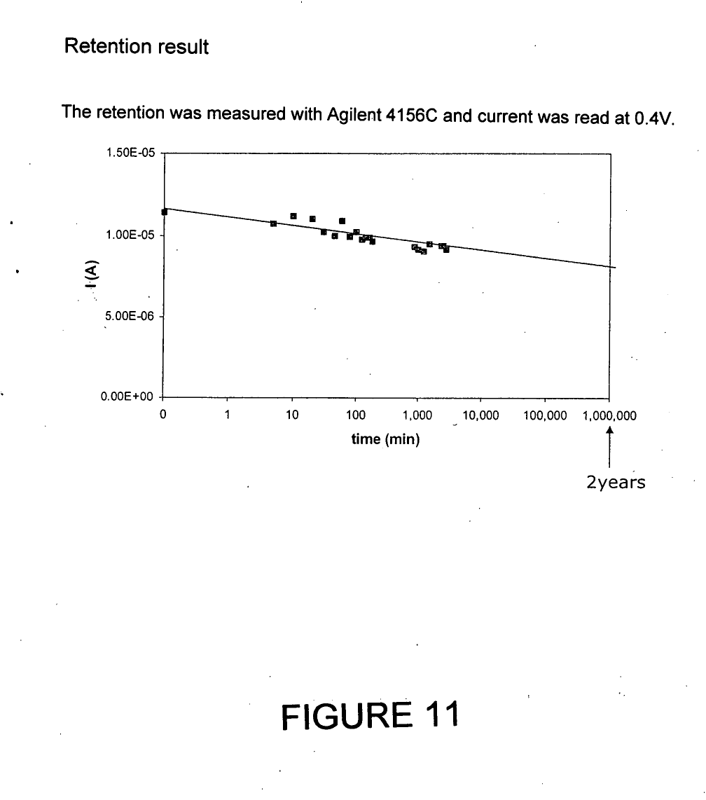

It has also been found that the present method, utilizing electronic switching as described above, provides greatly improved data retention when compared to an ionic switching approach. FIG. 11 illustrates data retention times for a programmed device read with Vᵣ=0.4 volts applied. As will be seen, read current through the device 130 drops only very slightly over a very long period of time. This clearly indicates that the programmed device 130 retains its conductive, i.e., programmed state over a very long period of time.

The device 130 has demonstrated this strong stability at high temperatures, for example, up to 150° C.

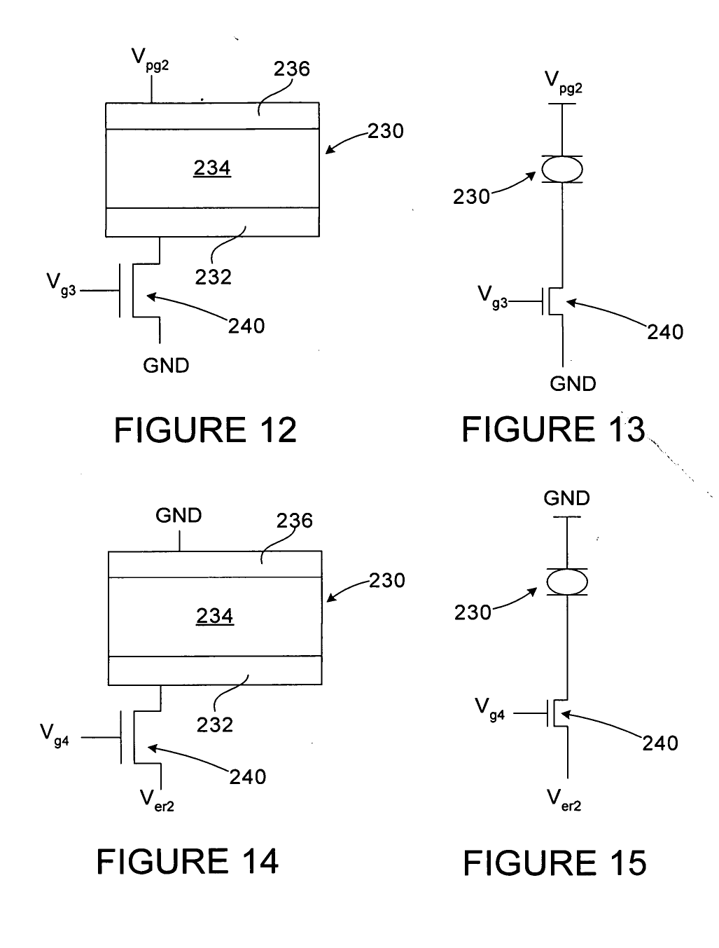

FIGS. 12-15 illustrate a second embodiment of the invention. This memory device 230 includes a copper electrode 232, a copper oxide active layer 234 on and in contact with the copper electrode 232 (formed by oxidation of the copper electrode), and a titanium electrode 236 on and in contact with the active layer 234, so that the active layer 234 is between the electrodes 232, 236. The device 230 is provided in series with a current limiting transistor 240 as described above. Similar to the previous embodiment, in programming the memory device 230, a positive voltage V_{pg2} is applied to the electrode 236, with ground applied to electrode 232, so that an electrical potential is applied across the device 230 from higher to lower potential in the direction from the electrode 236 to the electrode 232. This causes electronic charge carriers in the form of electrons and/or holes to enter the active layer 234 and be held by traps preexisting in the active layer 234, similar to the previous embodiment, to provide that the overall memory device 230 adopts and is in a conductive, low-resistance (programmed) state. Reversing the electrical potential (i.e., applying positive voltage Vₑᵣ₂ to the electrode 236 with ground applied to the electrode 232), so that an electrical potential is applied across the device 230 from higher to lower potential in the direction from the electrode 232 to the electrode 236, causes the electronic charge carriers to leave the active layer 234, so that the overall memory device 230 adopts and is in a high-resistance (erased) state. Similar to the previous embodiment, the switching from one state to the other is very rapid, and the transistor 240, using selected gate voltages V_{g3}, V_{g4} respectively, acts to limit current through the device 230 to ensure low-power operation.

In both embodiments, the process of forming the active layer itself causes traps to be formed in the active layer. The active layers are undoped in the sense that they are formed with the intention of being undoped, and that introduction of dopants is not necessary for practice of the invention.

It will be seen that herein is provided an approach wherein a memory device may be switched from one state to another in a very rapid manner, with very low power. Using this approach, the memory device is capable of maintaining its selected state in a stable manner for a very long period of time.

The foregoing description of the embodiments of the invention has been presented for purposes of illustration and description. It is not intended to be exhaustive or to limit the invention to the precise form disclosed. Other modifications or variations are possible in light of the above teachings.

The embodiments were chosen and described to provide the best illustration of the principles of the invention and its practical application to thereby enable one of ordinary skill of the art to utilize the invention in various embodiments and with various modifications as are suited to the particular use contemplated. All such modifications and variations are within the scope of the invention as determined by the appended claims when interpreted in accordance with the breadth to which they are fairly, legally and equitably entitled.

1. A method of changing the state of a memory device comprising first and second electrodes and an undoped active layer between the first and second electrodes, the method comprising moving electronic charge carriers into the active layer.

2. The method of claim 1 and further comprising the step of limiting current through the memory device while changing the state of the memory device.

3. The method of claim 1 wherein the active layer is copper oxide.

4. The method of claim 1 and further comprising a passive layer between the first and second electrodes.

5. The method of claim 1 wherein the electronic charge carriers are moved into traps within the active layer.

6. The method of claim 1 wherein the memory device is changed from a higher resistance state to a lower resistance state.

7. A method of changing the state of a memory device comprising first and second electrodes and an undoped active layer between the first and second electrodes, the method comprising moving electronic charge carriers from the active layer.

8. The method of claim 7 and further comprising the step of limiting current through the memory device while changing the state of the memory device.

9. The method of claim 7 wherein the active layer is copper oxide.

10. The method of claim 7 and further comprising a passive layer between the first and second electrodes.

11. The method of claim 7 wherein the electronic charge carriers are moved from traps within the active layer.

12. The method of claim 7 wherein the memory device is changed from a lower resistance state to a higher resistance state.

13. A method of changing the state of a memory device from a higher resistance state to a lower resistance state, the memory device comprising a first electrode, a second electrode, a passive layer between the first and second electrodes, and an active layer between the first and second electrodes, the method comprising moving electronic charge carriers into the active layer.

14. The method of claim 13 wherein the electronic charge carriers move into traps within the active layer.

15. The method of claim 13 and further comprising the step of limiting current through the memory device while changing the state of the memory device.

16. The method of claim 13 wherein the passive layer is on and in contact with the first electrode, the active layer is on and in contact with the passive layer, and the second electrode is on and in contact with the active layer.

17. A method of changing the state of a memory device from a lower resistance state to a higher resistance state, the memory device comprising a first electrode, a second electrode, a passive layer between the first and second electrodes, and an active layer between the first and second electrodes, the method comprising moving electronic charge carriers from the active layer.

18. The method of claim 17 wherein the electronic charge carriers move from traps within the active layer.

19. The method of claim 17 and further comprising the step of limiting current through the memory device while changing the state of the memory device.

20. The method of claim 17 wherein the passive layer is on and in contact with the first electrode, the active layer is on and in contact with the passive layer, and the second electrode is on and in contact with the active layer.

21. A method of changing the state of a memory device comprising first and second electrodes and an active layer between the first and second electrodes, the method comprising selecting a level of current limit through the memory device, and applying an electrical potential across the first and second electrodes.

22. The method of claim 21 and further comprising the step of limiting current through the memory device to the selected level.

23. The method of claim 22 wherein the memory device is changed from a higher resistance state to a lower resistance state.

24. The method of claim 22 wherein the memory device is changed from a lower resistance state to a higher resistance state.

25. The method of claim 21 wherein the active layer is on and in contact with the first electrode, and the second electrode is on and in contact with the active layer.

26. The method of claim 21 and further comprising a passive layer between the first and second electrodes.
